(19) United States
(12) Patent Application Publication
(10) Pub. No.: US 2009/0295610 A1
(43) Pub. Date: Dec. 3, 2009

(54) A/D converter having arbitration circuit which arbitrates operations of sample-and-hold circuit and comparator

(75) Inventor: Mitsuhide Yoshimoto, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 12/453,552

(22) Filed: May 14, 2009

(30) Foreign Application Priority Data
May 29, 2008 (JP) 2008-140813

(51) Int. Cl. H03M 1/12

(52) U.S. Cl. 341/122

(57) ABSTRACT

When an A/D conversion start request for a potential supplied to an analog input terminal is generated during a conversion operation for converting a potential supplied to an analog input terminal into a digital value being executed, an A/D converter makes a sample-and-hold (SH) circuit execute a sampling operation for sampling the potential supplied to the analog input terminal and a holding operation for holding it as an analog value. At this time, the conversion operation is suspended. Consequently, the A/D converter can avoid the influence of power supply noise arising from the sampling operation in the SH circuit.

### INCORPORATION BY REFERENCE

This application is based upon and claims the benefit of priority from Japanese Patent Application No. 2008-140813 which was filed on May 29, 2008, the disclosure of which is incorporated herein in its entirety by reference.

### BACKGROUND OF THE INVENTION

1. Field of the Invention

The present invention relates to an A/D converter that converts an analog value supplied to an analog terminal into a digital value.

2. Description of Related Art

In recent years, especially in the motor control field, the enhancement of motor control accuracy has been expected. From that point of view, there is a need for, in terms of a plurality of analog input channels (analog input terminals), performing a comparison operation for comparing potentials (analog values) supplied to the analog input terminals at a same time, with a reference analog value, and outputting (converting) the results of the comparisons as digital values. This is because, although in the case of three-phase motor control, the rotational position of a motor is estimated by measuring signals obtained by converting the currents of u-phase, v-phase and w-phase power supply lines into voltages, the measurement would be conducted at the rotational positions of the motor different from one another where there is difference in measurement time, which results in lowering of the motor control accuracy. Also, even during AID conversion (comparison operation) in response to a conversion request for a purpose other than a rotational position estimation, when a conversion request for rotational position measurement is generated, it is necessary to perform a sampling operation for sampling the potentials supplied to the analog input terminals and perform a holding operation for holding the then analog values, without delay. If the A/D conversion that is underway cannot be interrupted, then it is necessary to perform the sampling operation and the holding operation for the potentials (analog values) supplied to the analog input terminals, for rotational position measurement during performing the A/D conversion.

Under such circumstances, in order to convert potentials (analog values) supplied to analog input terminals at a same time into digital values, there is a need for an A/D converter including a plurality of sample-and-hold circuits, and capable of performing sampling and holding operations for potentials supplied to the analog input terminals even during an A/D conversion (comparison operation), and providing highly-accurate A/D conversion.

Here, a signal processing device, which is the technique described in Japanese Patent Laid-Open No. 2006-080646, will be introduced.

As illustrated in FIG. 1, a signal processing device 1 includes a first circuit unit 2 including a digital circuit, a second circuit unit 3 including an analog signal holding circuit 3a, and control means 5. The control means 5 controls the operation of the first circuit unit 2 and the second circuit unit 3. In such configuration, the following operation control is performed. The operation of the digital circuit is started via a signal sent from the control means 5 to the first circuit unit 2, and the first circuit unit 2 notifies the control means 5 of the end of an operation of the digital circuit. In this case, an analog signal is held via a signal sent from the control means 5 to the analog signal holding circuit 3a. Consequently, the analog signal is reliably held after the end of the digital circuit operation.

The signal processing device 1 further includes a signal output unit 4. The control means 5 controls the operation of the first circuit unit 2, the second circuit unit 3 and the signal output unit 4. In such configuration, the following operation control is performed in addition to the aforementioned operation control. The second circuit unit 3 notifies the control means 5 of the end of an operation of the analog signal holding circuit 3a. In this case, a signal output operation is performed via a signal sent from the control means 5 to the signal output unit 4. Consequently, the operation control is performed so that the digital circuit operation, the signal holding operation and the signal output operation do not overlap with one another in terms of time period.

### SUMMARY

The technique described in Japanese Patent Laid-Open No. 2006-080646 is intended for reducing the influence of power supply noise arising from operations of parts other than an A/D converter, which are typified by the digital circuit and the signal output circuit. However, the technique is characterized in that it is configured so as to avoid operations of the digital circuit and/or the signal output circuit from being performed at the same time, and thus, it cannot be employed as a measure to reduce the influence of power supply noise in the AID converter, which arises from a sampling operation during an A/D conversion (comparison operation). An analog circuit in an A/D converter is normally supplied with power from a single dedicated power supply, and thus, power supply noise in the AID converter is directly conveyed to the analog circuit via an inner power supply wiring. Accordingly, power supply noise in the AID converter will more seriously affect the A/D conversion accuracy, rather than power supply noise arising from operations of parts other than the AID converter.

An A/D converter (107) according to an exemplary aspect of the present invention includes a plurality of sample-and-hold circuits (hereinafter, “SH circuits”) (114 to 117), a comparator (112) and an arbitration circuit (109).

The plurality of SH circuits (114 to 117) are provided corresponding to a plurality of analog input terminals (101 to 104), respectively.

One SH circuit (117) from among the plurality of SH circuits (114 to 117) samples a potential supplied to one corresponding analog input terminal (104) from among the plurality of analog input terminals (101 to 104) and holds it as an analog value.

In this case, a comparator (112) compares the analog value held by the one SH circuit (117) and a reference analog value (111), and outputs the result of the comparison as a digital value (113).

For example, during a conversion operation for converting the potential supplied to the one analog input terminal (104) into the digital value (113) being executed, an AID conversion operation start request (106) is generated for a potential supplied to another analog input terminal (102) from among the plurality of analog input terminals (101 to 104).

In this case, an arbitration circuit (109) controls another SH circuit (115) corresponding to the another analog input terminal (102), from among the plurality of SH circuit (114 to 117), and the comparator (112) so as to sample the potential supplied to the another analog input terminal (102) with the conversion operation, which is being executed, suspended, and hold it as an analog value.

The A/D converter (107) according to an exemplary aspect of the present invention, when an AID conversion start request (106) is generated for a potential supplied to another analog input terminal (102) during a conversion operation being executed, makes another SH circuit (115) corresponding to the another analog input terminal (102) execute a sampling operation for sampling the potential supplied to the another analog input terminal (102) and a holding operation for holding it as an analog value. At this time, the conversion operation is suspended. More specifically, if the comparator (112) is executing a comparison operation (AID conversion) for comparing an analog value held by an SH circuit (117) and a reference analog value (111), then the comparison operation is suspended. Consequently, the A/D converter (107) can avoid the influence of power supply noise arising from the sampling operation in the another SH circuit (115). As described above, even during an A/D conversion (comparison operation), it is possible to execute a sampling operation and a holding operation for a potential supplied to another analog input terminal (102), enabling provision of highly-accurate A/D conversion in which the influence of power supply noise has been eliminated.

### BRIEF DESCRIPTION OF THE DRAWINGS

The above and other exemplary aspects, advantages and features of the present invention will be more apparent from the following description of certain exemplary embodiments taken in conjunction with the accompanying drawings, in which:

FIG. 1 illustrates a configuration of a technique described in Japanese Patent Laid-Open No. 2006-080646;

FIG. 2 illustrates a configuration of an AID converter 107 according to a first exemplary embodiment of the present invention;

FIG. 3 is a timing chart illustrating an operation of an A/D converter 107 according to a first exemplary embodiment of the present invention when a trigger 106, which is an A/D conversion request, is generated during a sample-and-hold circuit 117 executing a sampling operation;

FIG. 4 is a timing chart illustrating an operation of an A/D converter 107 according to a first exemplary embodiment of the present invention when a trigger 106, which is an A/D conversion request, is generated during a comparator 112 executing a comparison operation;

FIG. 5 is a timing chart for an operation of an A/D converter 107 according to a first exemplary embodiment of the present invention when setting suspension time T202 in FIG. 4;

FIG. 6 illustrates a configuration of an A/D converter 107 according to a second exemplary embodiment of the present invention; and

FIG. 7 is a timing chart illustrating an operation of an A/D converter 107 according to a second exemplary embodiment of the present invention when a sample-and-hold circuit 114 and a sample-and-hold circuit 115 perform sampling simultaneously during a comparator 112 executing a comparison operation.

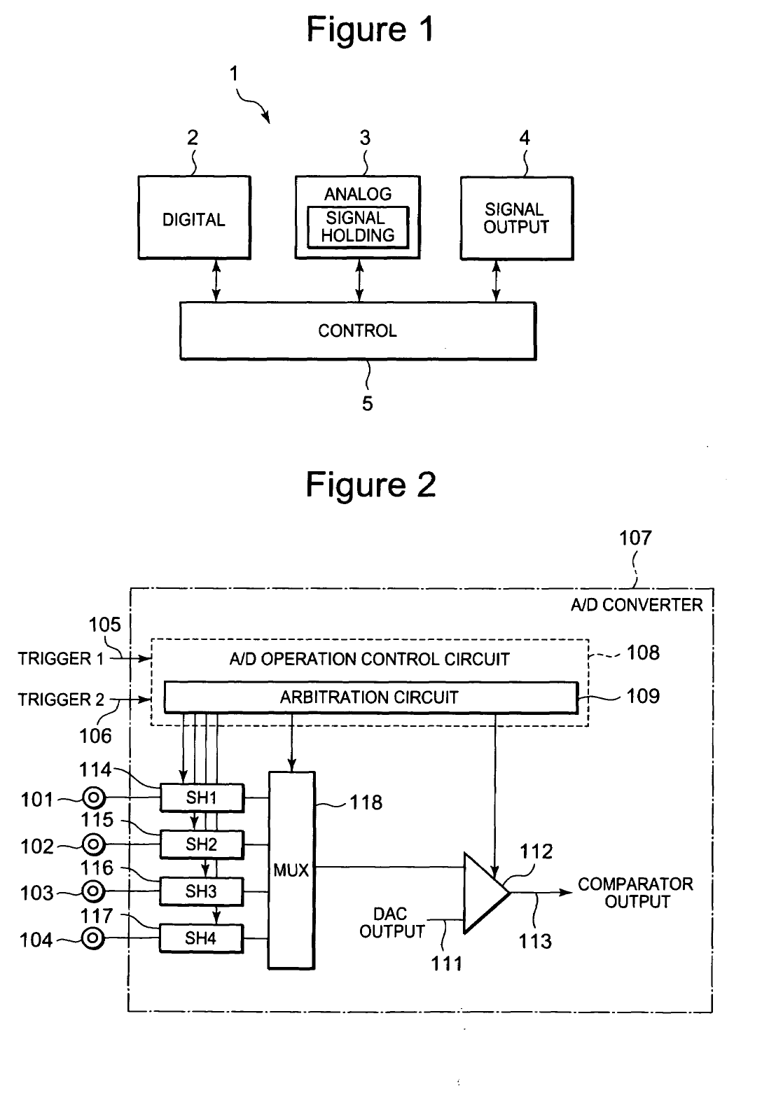

### DETAILED DESCRIPTION OF THE EXEMPLARY EMBODIMENTS

### First Exemplary Embodiment

### [Constitution]

FIG. 2 illustrates the configuration of an A/D converter 107 according to a first exemplary embodiment of the present invention. The A/D converter 107 includes sample-and-hold circuits (SH1 to SH4) 114 to 117, a multiplexer (MUX) 118, a comparator 112 and an A/D operation control circuit 108. Hereinafter, the sample-and-hold circuits 114 to 117 are referred to as the “SH circuits 114 to 117”.

Inputs of the SH circuits 114 to 117 are provided with analog input terminals 101 to 104, respectively. Potentials are supplied to the analog input terminals 101 to 104. Outputs of the SH circuits 114 to 117 are connected to inputs of the MUX 118. An output of the MUX 118 is connected to one of two inputs of the comparator 112. A reference analog value 111, which corresponds to a DAC (Digital Analog Converter) output, is supplied to the other input of the two inputs of the comparator 112. The A/D operation control circuit 108 is connected to the SH circuits 114 to 117, the MUX 118 and the comparator 112, and performs the overall control. In other words, it controls the SH circuits 114 to 117, the MUX 118 and the comparator 112.

For example, as a trigger 105 (Trigger 1), an A/D conversion start request is generated for a potential supplied to one analog input terminal from among the analog input terminals 101 to 104. In response to the trigger 105, one SH circuit corresponding to the one analog input terminal, from among the SH circuits 114 to 117, executes a sampling operation for sampling the potential supplied to the one analog input terminal, and executes a holding operation for holding the then analog value. In response to the trigger 105, the arbitration circuit 109 outputs a selection instruction to select the one SH circuit to the MUX 118, and outputs a comparison operation execution instruction to the comparator 112. In response to the selection instruction, the MUX 118 outputs the analog value held by the one SH circuit to the comparator 112. In response to the comparison operation execution instruction, the comparator 112 executes a comparison operation for comparing the analog value from the MUX 118 and the reference analog value 111, and outputs the result of that comparison as a digital value 113.

The A/D operation control circuit 108 includes an arbitration circuit 109. The arbitration circuit 109 monitors the SH circuits 114 to 117, the MUX 18 and the comparator 112, and arbitrates them.

### [Operation]

Next, as the operation of the A/D converter 107 according to the first exemplary embodiment of the present invention, the operation of the SH circuits 114 to 117, the MUX 18 and the comparator 112, and arbitration by means of the arbitration circuit 109 will be described.

As a trigger 105 (Trigger 1), a first A/D conversion start request is generated for a potential supplied to the analog input terminal 101 from among the analog input terminals 101 to 104. In response to the trigger 105, the SH circuit 114 corresponding to the analog input terminal 101, from among the SH circuits 114 to 117, executes a first sampling operation for sampling the potential supplied to the analog input terminal 101, and executes a first holding operation for holding the then first analog value. In response to the trigger 105, the arbitration circuit 109 outputs a selection instruction to select the SH circuit 114, to the MUX 118, and outputs a comparison operation execution instruction to the comparator 112. In response to the selection instruction, the MUX 118 outputs the first analog value held by the SH circuit 114, to the comparator 112. In response to the comparison operation execution instruction, the comparator 112 executes a first comparison operation for comparing the first analog value from the MUX 118 and the reference analog value 111.

During the comparator 112 executing the first comparison operation, as the next trigger 106 (Trigger 2), a second A/D conversion start request is generated for a potential supplied to the analog input terminal 102 from among the analog input terminals 101 to 104. In this case, the arbitration circuit 109 in the A/D operation control circuit 108 outputs a comparison operation suspension instruction to the comparator 112, as a delay request, which will be described later. The comparator 112 temporarily suspends the first comparison operation that is being executed, in response to the comparison operation suspension instruction. During the suspension period in which the comparator 112 is suspending the first comparison operation, the arbitration circuit 109 outputs a sampling operation execution instruction to the SH circuit 115 corresponding to the analog input terminal 102, from among the SH circuits 114 to 117. In response to the sampling operation execution instruction, the SH circuit 115 executes a second sampling operation for sampling the potential supplied to the analog input terminal 102, and executes a second holding operation for holding the then second analog value. After the SH circuit 115 executing the second sampling operation, the arbitration circuit 109 outputs a comparison operation restart instruction to the comparator 112 for cancellation of the delay request, which will be described later. In response to the comparison operation restart instruction, the comparator 112 restarts the first comparison operation that is being suspended, and outputs the result of that comparison as a first digital value 113.

After the comparator 112 outputting the first digital value 113, the arbitration circuit 109, in response to the trigger 106, outputs a selection instruction to select the SH circuit 115 to the MUX 118, and outputs a comparison operation execution instruction to the comparator 112. In response to the selection instruction, the MUX 118 outputs the second analog value held by the SH circuit 115 to the comparator 112. In response to the comparison operation execution instruction, the comparator 112 executes a second comparison operation for comparing the second analog value from the MUX 118 and the reference analog value 111, and outputs the result of that comparison as a second digital value 113.

Also, since the A/D converter 107 according to the first exemplary embodiment of the present invention is configured to have an SH circuit for each analog input terminal, it is possible to sample not only a potential supplied to the analog input terminal 101, but also potentials supplied to arbitrary analog input terminals 102 to 104, simultaneously, by means of the SH circuits 115 to 117 via the trigger 105 (A/D conversion start request).

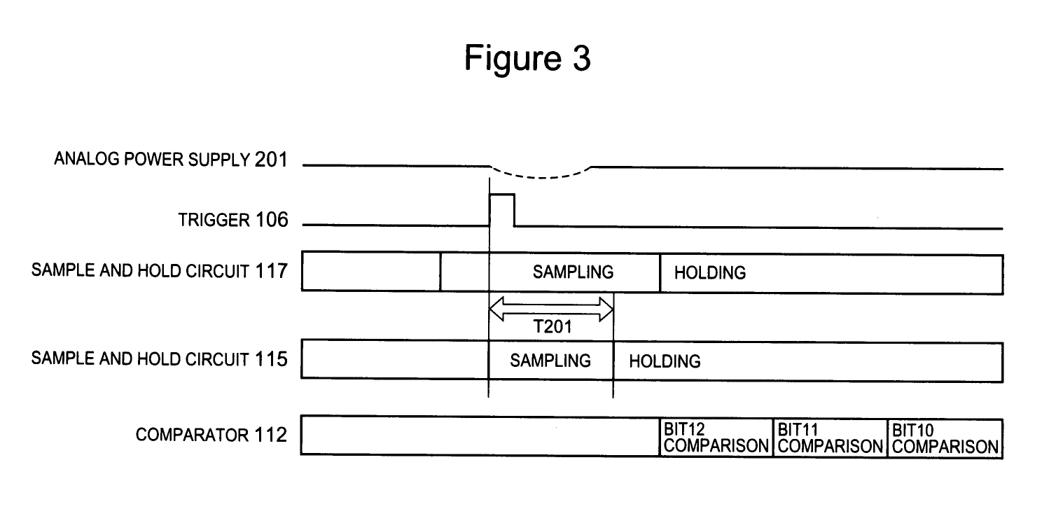

FIG. 3 is a timing chart illustrating an operation when a trigger 106, which is an A/D conversion request, is generated during the SH circuit 117 executing a sampling operation. Here, in FIG. 3, “bit12 comparison”, “bit11 comparison” and “bit10 comparison” performed by the comparator 112 indicate positions bit12, bit11 and bit10 of comparison between the second analog value and the DAC output, respectively.

First, as a trigger 105 (Trigger 1), a first A/D conversion start request is generated for a potential supplied to the analog input terminal 104 from among the analog input terminals 101 to 104. In response to the trigger 105, the SH circuit 117 corresponding to the analog input terminal 104, from among the SH circuits 114 to 117, executes a first sampling operation for sampling the potential supplied to the analog input terminal 104.

Next, during the SH circuit 117 executing the first sampling operation, as the next trigger 106 (Trigger 2), a second A/D conversion start request is generated for a potential supplied to the analog input terminal 102 from among the analog input terminals 101 to 104. It is assumed that this A/D conversion start request indicates that the SH circuit 115 corresponding to the analog input terminal 102, from among the SH circuits 114 to 117, has higher priority over that of the SH circuit 117.

In this case, the arbitration circuit 109 in the A/D operation control circuit 108 outputs a sampling operation suspension instruction to the SH circuit 117, as a delay request, which will be described later. The SH circuit 117 temporarily suspends the first sampling operation that is being executed, in response to the sampling operation suspension instruction. During a suspension period T201 in which the SH circuit 117 is suspending the first sampling operation, the arbitration circuit 109 outputs a sampling operation execution instruction to the SH circuit 115. This suspension period T201 represents time required for the SH circuits 114 to 117 to sample potentials supplied to the analog input terminals 101 to 104, respectively. In response to the sampling operation execution instruction, the SH circuit 115 executes a second sampling operation for sampling the potential supplied to the analog input terminal 102, and executes a second holding operation for holding the then second analog value. In this case, although an analog power supply 201 fluctuates in the suspension period T201 during the SH circuit 115 executing the second sampling operation, the SH circuit 117 is suspending the first sampling operation, and thus, the A/D converter 107 can avoid the influence of power supply noise arising from the first sampling operation in the SH circuit 115.

After the SH circuit 115 executing the second sampling operation, the arbitration circuit 109, in response to the aforementioned trigger 106, outputs a selection instruction to select the SH circuit 115 to the MUX 118, and outputs a comparison operation execution instruction to the comparator 112. In response to the selection instruction, the MUX 118 outputs the second analog value held by the SH circuit 115 to the comparator 112. In response to the comparison operation execution instruction, the comparator 112 executes a second comparison operation for comparing the second analog value from the MUX 118 and the reference analog value 111, and outputs the result of that comparison as a second digital value 113.

After the comparator 112 outputting the second digital value 113, the arbitration circuit 109 outputs a sampling operation restart instruction to the SH circuit 117 for cancellation of the delay request, which will be described later. In response to the sampling operation restart instruction, the SH circuit 117 restarts the first sampling operation that is being suspended, and executes a first holding operation for holding the then first analog value. After the SH circuit 117 executing the first sampling operation, the arbitration circuit 109, in response to the aforementioned trigger 105, outputs a selection instruction to select the SH circuit 117 to the MUX 118, and outputs a comparison operation execution instruction to the comparator 112. In response to the selection instruction, the MUX 118 outputs the first analog value held by the SH circuit 117 to the comparator 112. In response to the comparison operation execution instruction, the comparator 112 executes a first comparison operation for comparing the first analog value from the MUX 118 and the reference analog value 111, and outputs the result of that comparison as a first digital value 113.

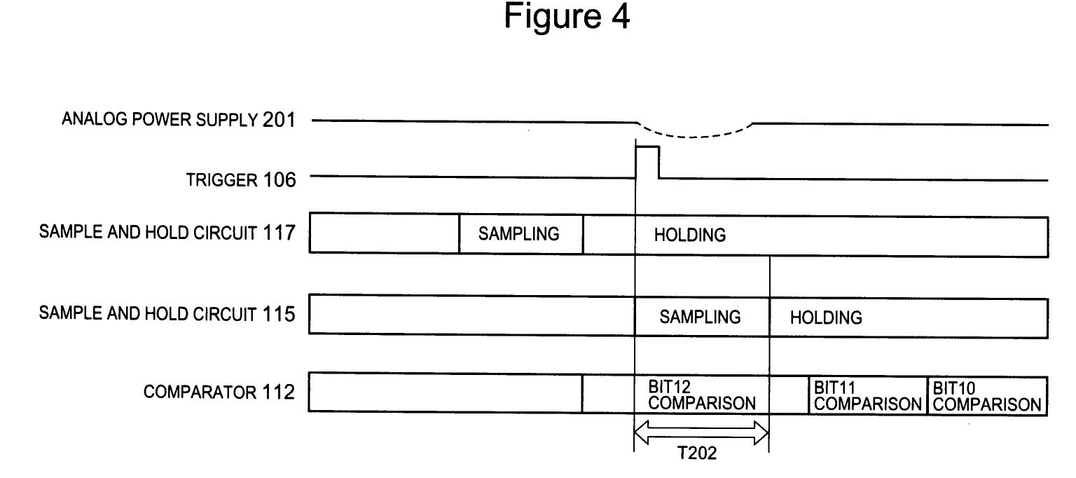

FIG. 4 is a timing chart illustrating an operation when a trigger 106, which is an A/D conversion request, is generated during the comparator 112 executing a comparison operation. Here, in FIG. 4, “bit12 comparison”, “bit11 comparison”, “bit10 comparison” performed by the comparator 112 represent positions bit12, bit11 and bit10 of comparison between the second analog value and the DAC output, respectively.

First, as a trigger 105 (Trigger 1), a first A/D conversion start request is generated for a potential supplied to the analog input terminal 104 from among the analog input terminals 101 to 104. In response to the trigger 105, the SH circuit 117 corresponding to the analog input terminal 104, from among the SH circuits 114 to 117, executes a first sampling operation for sampling a potential supplied to the analog input terminal 104, and executes a first holding operation to the then first analog value. The arbitration circuit 109 outputs a selection instruction to select the SH circuit 117 to the MUX 118, in response to the trigger 105. The MUX 118 outputs the first analog value held by the SH circuit 117 to the comparator 112, in response to the selection instruction. The comparator 112 executes a comparison operation for comparing the first analog value from the MUX 118 and the reference analog value 111.

Next, during the comparator 112 executing a first comparison operation, as the next trigger 106 (Trigger 2), a second A/D conversion start request is generated for a potential supplied to the analog input terminal 102 from among the analog input terminals 101 to 104.

In this case, the arbitration circuit 109 in the A/D operation control circuit 108 outputs a comparison operation suspension instruction to the comparator 112 as a delay request, which will be described later. The comparator 112 temporarily suspends the comparison operation that is being executed, in response to the comparison operation suspension instruction. During a suspension period T202 in which the comparator 112 is suspending the first comparison operation, the arbitration circuit 109 outputs a sampling operation execution instruction to the SH circuit 115 corresponding to the analog input terminal 102, from among the SH circuits 114 to 117. This suspension period T202 is time corresponding to the suspension period T201, and represents time required for the SH circuits 114 to 117 to sample potentials supplied to the analog input terminals 101 to 104, respectively. In response to the sampling operation execution instruction, the SH circuit 115 executes a second sampling operation for sampling the potential supplied to the analog input terminal 102, and executes a second holding operation for holding the then second analog value. In this case, although the analog power supply 201 fluctuates in the suspension period T202 during the SH circuit 115 executing the second sampling operation, the comparator 112 is suspending the first comparison operation, and thus, the A/D converter 107 can avoid the influence of power supply noise arising from the first sampling operation in the SH circuit 115.

After the SH circuit 115 executing the second sampling operation, the arbitration circuit 109 outputs a comparison operation restart instruction to the comparator 112 for cancellation of the delay request, which will be described later. In response to the comparison operation restart instruction, the comparator 112 restarts the first comparison operation that is being suspended, and outputs the result of the then comparison as a first digital value 113.

After the comparator 112 outputting the first digital value 113, the arbitration circuit 109, in response to the aforementioned trigger 106, outputs a selection instruction to select the SH circuit 115 to the MUX 118, and outputs a comparison operation execution instruction to the comparator 112. In response to the selection instruction, the MUX 118 outputs the second analog value held by the SH circuit 115 to the comparator 112. In response to the comparison operation execution instruction, the comparator 112 executes a second comparison operation for comparing the second analog value from the MUX 118 and the reference analog value 111, and outputs the result of that comparison as a second digital value 113.

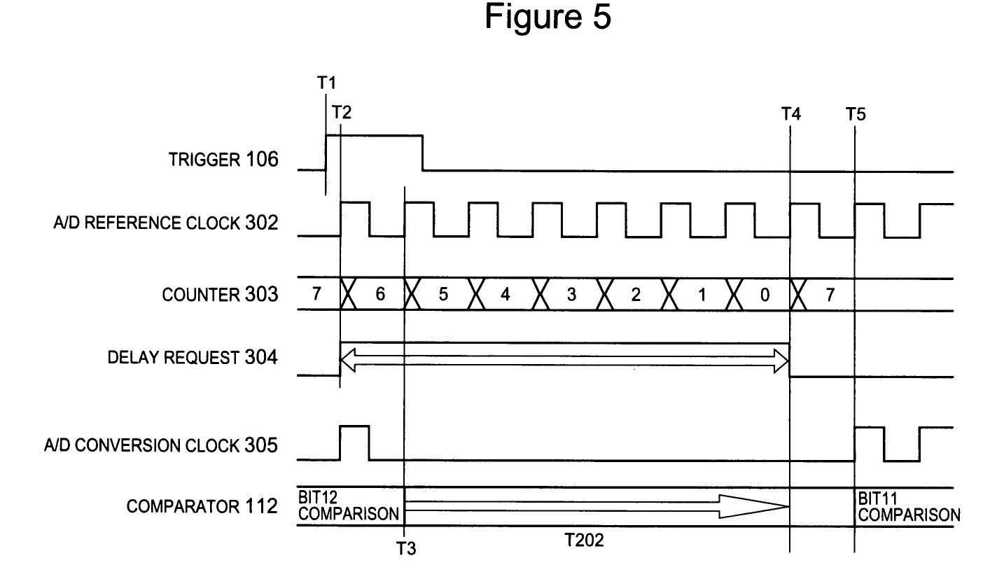

FIG. 5 is a timing chart illustrating an operation when setting the suspension time T202 in FIG. 4.

Here, it is assumed that: an A/D reference clock 302, which is a clock signal, is supplied to the A/D operation control circuit 108; and the arbitration circuit 109 supplies an A/D conversion clock 305 synchronized with the A/D reference clock 302 to the comparator 112. Furthermore, it is assumed that the arbitration circuit 109 includes a counter 303.

When the trigger 106 is generated at timing T1, the arbitration circuit 109 in the A/D operation control circuit 108 generates a delay request 304, which is the aforementioned delay request, at the immediately-following timing T2 on the rising edge of the A/D reference clock 302. At that time, the counter 303 counts according to the A/D reference clock 302.

At timing T3, which is one clock after the timing T2, the arbitration circuit 109 suspends the A/D conversion clock 305 on the rising edge of the A/D reference clock 302.

At timing T4, it is assumed that the value of the counting performed by the counter 303 from the generation of the delay request 304 has reached a set counter value. In this case, the arbitration circuit 109 cancels the delay request 304 on the rising edge of the A/D reference clock 302.

At timing T5, which is one clock after the timing T4, the arbitration circuit 109 restarts the A/D conversion clock 305.

The set counter value corresponds to the aforementioned suspension time T202. The suspension time T202, i.e., the set counter value differs depending on the time required for the system (the A/D converter 107 itself or the system including the A/D converter 107) to recover from the power supply noise. Accordingly, the suspension time T202 is set to an amount of time enabling the A/D converter 107 to avoid the influence of power supply noise. The amount of time enabling the A/D converter 107 to avoid the influence of power supply noise is determined by measuring it in advance.

### [Advantage]

An advantage of the A/D converter 107 according to the first exemplary embodiment of the present invention will be described.

In the A/D converter 107 according to the first exemplary embodiment of the present invention, when a first A/D conversion start request is generated for a potential supplied to the analog input terminal 104 from among the analog input terminals 101 to 104, the SH circuit 117 corresponding to the analog input terminal 104, from among the SH circuits 114 to 117, executes a first sampling operation and a first holding operation. During the comparator 112 executing a first comparison operation (i.e., during A/D conversion), a second A/D conversion start request is generated for a potential supplied to the analog input terminal 102 from among the analog input terminals 101 to 104. In this case, the arbitration circuit 109 controls the SH circuits 114 to 117 and the comparator 112 so as to suspend the conversion operation for converting the potential supplied to the analog input terminal 104 into a first digital value 113. More specifically, it controls the comparator 112 so as to suspend the first comparison operation (A/D conversion) that is being executed. At this time, it controls the SH circuit 115 corresponding to the analog input terminal 102, from among the SH circuits 114 to 117, so as to execute a second sampling operation and a second holding operation.

As described above, the A/D converter 107 according to the first exemplary embodiment of the present invention, when an A/D conversion start request 106 is generated for a potential supplied to the analog input terminal 102 during a conversion operation is being executed, makes the SH circuit 115 corresponding to the analog input terminal 102 execute a second sampling operation and a second holding operation. At this time, it makes the conversion operation be suspended. In other words, it makes the comparator 112 suspend the first comparison operation (A/D conversion). Consequently, the A/D converter 107 can avoid the influence of power supply noise arising from the second sampling operation in the SH circuit 115. As described above, even during A/D conversion (first comparison operation), it is possible to execute a second sampling operation and a second holding operation for the potential supplied to the analog input terminal 102, enabling provision of highly-accurate A/D conversion in which the influence of power supply noise has been eliminated.

Also, in the A/D converter 107 according to the first exemplary embodiment of the present invention, after the SH circuit 115 executing the second sampling operation, the arbitration circuit 109 controls the comparator 112 so as to restart the first comparison operation that is being suspended and output a first digital value 113.

As described above, the A/D converter 107 according to the first exemplary embodiment of the present invention, even a second A/D conversion start request is generated during a first A/D conversion (first comparison operation), enables provision of highly-accurate A/D conversion in which the influence of power supply noise has been eliminated, for both the first A/D conversion that is underway and a second A/D conversion executed in response to the second A/D conversion start request.

Also, in the A/D converter 107 according to the first exemplary embodiment of the present invention, when a first A/D conversion start request is generated for a potential supplied to the analog input terminal 104 from among the analog input terminals 101 to 104, the SH circuit 117 corresponding to the analog input terminal 104, from among the SH circuits 114 to 117, executes a first sampling operation. At this time, a second A/D conversion start request is generated for a potential supplied to the analog input terminal 102 from among the analog input terminals 101 to 104. In this case, the arbitration circuit 109 controls the SH circuit 117 so as to suspend the first sampling operation that is being executed, controls the SH circuit 115 corresponding to the analog input terminal 102, from among the SH circuits 114 to 117, so as to execute a second sampling operation and a second holding operation, and controls the comparator 112 so as to execute a second comparison operation and output a second digital value 113. After the comparator 112 outputting the second digital value 113, the arbitration circuit 109 controls the SH circuit 117 so as to restart the first sampling operation that is being suspended and execute a first holding operation, and controls the comparator 112 so as to execute a first comparison operation and output a first digital value 113.

As described above, in the A/D converter 107 according to the first exemplary embodiment of the present invention, the arbitration circuit 109, when making the SH circuit 115 execute the second sampling operation and the second holding operation, makes the SH circuit 117 suspend the first sampling operation to avoid the influence of power supply noise arising from the second sampling operation of the SH circuit 115. Accordingly, the A/D converter 107 according to the first exemplary embodiment of the present invention, even when a second A/D conversion start request is generated during a first sampling operation, enables provision of highly-accurate A/D conversion in which the influence of power supply noise has been eliminated, for both of the first sampling operation that is being executed, and a second sampling operation executed in response to the second A/D conversion start request.

Furthermore, for the A/D converter 107 of the first exemplary embodiment of the present invention, it is preferable that: the aforementioned suspension times T201 and T202 represent time required for the SH circuits 114 to 117 to sample potentials supplied to the analog input terminals 101 to 104, respectively; and they represent an amount of time enabling the A/D converter 107 to avoid the influence of power supply noise. In this case, it is preferable to determine the amount of time enabling the A/D converter 107 to avoid from the influence of power supply noise, by measuring it in advance.

### Second Exemplary Embodiment

In a second exemplary embodiment, description that will be repetition of the description in the first exemplary embodiment will be omitted.

### [Constitution]

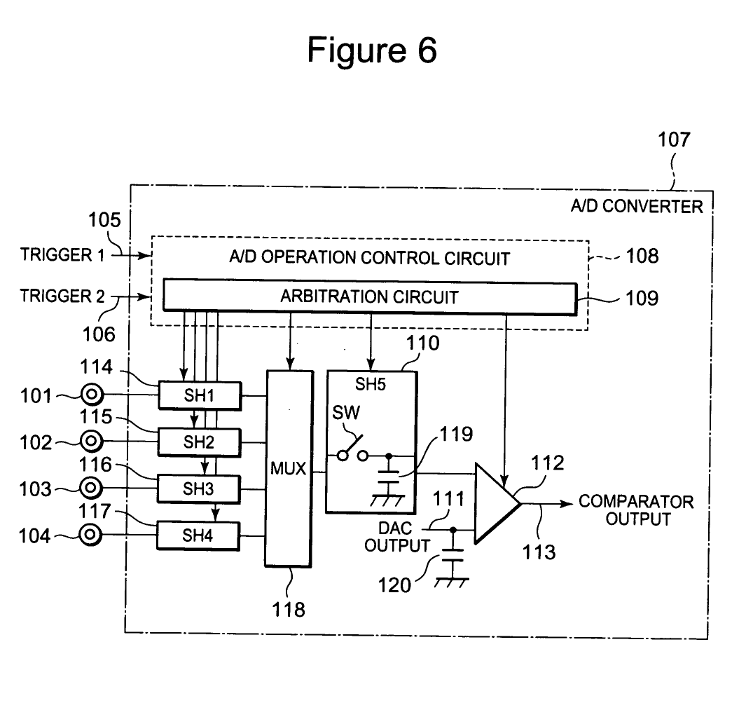

FIG. 6 illustrates the configuration of an A/D converter 107 according to a second exemplary embodiment of the present invention. The A/D converter 107 further includes a SH circuit for relay 110 provided between a MUX 118 and a comparator 112. The SH circuit 110 for relay includes a switch SW and a first capacitor 119. The switch SW is connected to an output of the MUX 118 and one of the inputs of the comparator 112. One terminal of the first capacitor 119 is connected to the output of MUX 118 and the one of the inputs of the comparator 112, and the other terminal is grounded.

The A/D converter 107 further includes a second capacitor 120. One terminal of the second capacitor 120 is connected to the other input of the comparator 112, and the other terminal is grounded. In the second capacitor 120, a charge corresponding to the aforementioned reference analog value 111 is stored.

The arbitration circuit 109 monitors SH circuits 114 to 117, the MUX 118, the SH circuit for relay 110 and the comparator 112, and arbitrate them.

### [Operation]

As a trigger 105 (Trigger 1), a first A/D conversion start request is generated for a potential supplied to an analog input terminal 104 from among the analog input terminals 101 to 104. In response to the trigger 105, the SH circuit 117 corresponding to the analog input terminal 104, from among the SH circuit 114 to 117, executes a first sampling operation for sampling the potential supplied to the analog input terminal 104, and executes a first holding operation for holding the then first analog value. In response to the trigger 105, the arbitration circuit 109 outputs a selection instruction to select the SH circuit 117 to the MUX 118, outputs a first switching instruction to the SH circuit for relay 110, and outputs a comparison operation execution instruction to the comparator 112. In response to the selection instruction, the MUX 118 outputs the first analog value held by the SH circuit 117 to the SH circuit for relay 110. In response to the first switching instruction, the SH circuit for relay 110 turns on the switch SW to store a charge corresponding to the first analog value in the first capacitor 119. In response to the comparison operation execution instruction, the comparator 112 executes a first comparison operation for comparing the first analog value, which corresponds to a potential supplied to the first capacitor 119 and a reference analog value 111, which corresponds to a potential supplied to the second capacitor 120, and outputs the result of that comparison as a first digital value 113. After the comparator 112 outputting the first digital value 113, the arbitration circuit 109 outputs a second switching instruction to the SH circuit for relay 110. In response to the second switching instruction, the SH circuit for relay 110 turns off the switch SW.

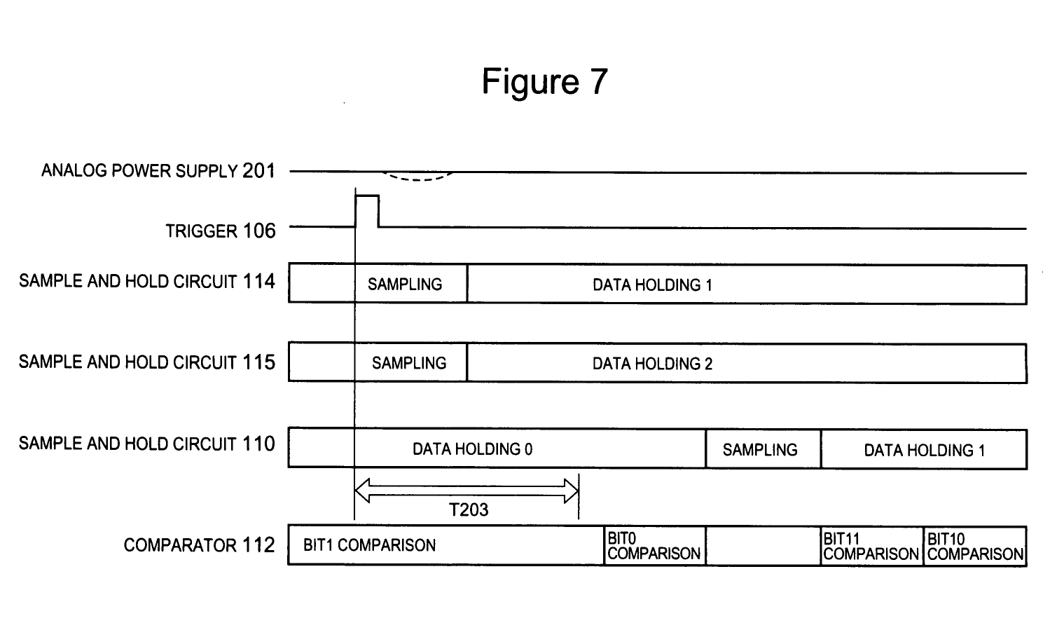

FIG. 7 is a timing chart illustrating an operation when the SH circuit 114 and the SH circuit 115 perform sampling simultaneously during the comparator 112 executing a comparison operation. Here, in FIG. 7, “bit1 comparison”, “bit0 comparison”, “bit11 comparison”, “bit10 comparison” performed by the comparator 112 represent positions bit12, bit11 and bit10 of comparison between the second analog value and a DAC output. Also, it is assumed that the SH circuits 114 to 117 are prioritized in the order of the SH circuits 114, 115, 116 and 117.

During the comparator 112 executing a first comparison operation, as the next trigger 106 (Trigger 2), a second A/D conversion start request is generated simultaneously for potentials supplied to the analog input terminals 102 and 101 from among the analog input terminals 101 to 104.

In this case, the arbitration circuit 109 in an A/D operation control circuit 108 outputs a comparison operation suspension instruction to the comparator 112 as a delay request, which has been described above. The comparator 112 temporarily suspends the comparison operation that is being executed, in response to the comparison operation suspension instruction. During a suspension period T203 in which the comparator 112 is suspending the first comparison operation, the arbitration circuit 109 outputs a sampling operation execution instruction to the SH circuits 115 and 114 corresponding to the analog input terminals 102 and 101, from among the SH circuits 114 to 117. In response to the sampling operation execution instruction, the SH circuit 115 executes a second sampling operation for sampling the potential supplied to the analog input terminal 102, and executes a second holding operation for holding the then second analog value. In response to the sampling operation execution instruction, the SH circuit 114 executes a third sampling operation for sampling the potential supplied to the analog input terminal 101, and executes a third holding operation for holding the then third analog value.

After the SH circuits 115 and 114 executing the second and third sampling operations, respectively, the arbitration circuit 109 outputs a comparison operation restart instruction to the comparator 112 for cancellation of the delay request, which has been described above. In response to the comparison operation restart instruction, the comparator 112 restarts the first comparison operation that is being suspended, and outputs the result of that comparison as a first digital value 113.

After the comparator 112 outputting the first digital value 113, the arbitration circuit 109, in response to the aforementioned trigger 106 and according to the aforementioned priority order, outputs a selection instruction to select the SH circuit 114 to the MUX 118, outputs a first switching instruction to the SH circuit for relay 110, and outputs a comparison operation execution instruction to the comparator 112. In response to the selection instruction the MUX 118 outputs the third analog value SH held by the circuit 114 to the SH circuit for relay 110. In response to the first switching instruction, the SH circuit for relay 110 turns on the switch SW to store a charge corresponding to the third analog value in the first capacitor 119. In response to the comparison operation execution instruction, the comparator 112 executes a third comparison operation for comparing a third analog value, which corresponds to a potential supplied to the first capacitor 119, and the reference analog value 111, which corresponds to a potential supplied to the second capacitor 120, and outputs the result of that comparison as a third digital value 113. After the comparator 112 outputting the third digital value 113, the arbitration circuit 109 outputs a second switching instruction to the SH circuit for relay 110. The SH circuit for relay 110 turns off the switch SW in response to the second switching instruction.

After the comparator 112 outputting the third digital value 113, the arbitration circuit 109, in response to the aforementioned trigger 106 and according to the aforementioned priority order, outputs a selection instruction to select the SH circuit 115 to the MUX 118, outputs a first switching instruction to the SH circuit for relay 110, and outputs a comparison operation execution instruction to the comparator 112. In response to the selection instruction, the MUX 118 outputs the second analog value held by the SH circuit 115 to the SH circuit for relay 110. In response to the first switching instruction, the SH circuit for relay 110 turns on the switch SW to store a charge corresponding to the second analog value in the first capacitor 119. In response to the comparison operation execution instruction, the comparator 112 executes a second comparison operation for comparing a second analog value, which corresponds to a potential supplied to the first capacitor 119, and the reference analog value 111, which corresponds to a potential supplied to the second capacitor 120, and outputs the result of that comparison as a second digital value 113. After the comparator 112 outputting the second digital value 113, the arbitration circuit 109 outputs a second switching instruction to the SH circuit for relay 110. The SH circuit for relay 110 turns off the switch SW in response to the second switching instruction.

### [Advantage]

An advantage of the A/D converter 107 according to the second exemplary embodiment of the present invention will be described.

In the A/D converter 107 according to the second exemplary embodiment of the present invention, the SH circuit for relay 110 and the comparator 112 are arranged in the vicinity of each other without providing the MUX 118 therebetween, enabling maintenance of the symmetry between the first capacitor 119 in the SH circuit for relay 110 and the second capacitor 120 for a DAC output 111. Thus, the performance of the comparator can be enhanced in comparison to that of the first exemplary embodiment, enabling provision of an A/D conversion with higher accuracy.

Further, it is noted that Applicant's intent is to encompass equivalents of all claim elements, even if amended later during prosecution.

What is claimed is:

1. An A/D converter, comprising:
a plurality of sample-and-hold circuits (hereinafter, “SH circuits”) provided corresponding to a plurality of analog input terminals, respectively, in which one SH circuit from among the plurality of SH circuits samples a potential supplied to one corresponding analog input terminal from among the plurality of analog input terminals, and holds the potential as an analog value;
a comparator that compares the analog value held by the one SH circuit and a reference analog value, and outputs a result of the comparison as a digital value; and
an arbitration circuit that, when an A/D conversion start request is generated for a potential supplied to another analog input terminal from among the plurality of analog input terminals during a conversion operation for converting the potential supplied to the one analog input terminal into the digital value being executed, suspends the conversion operation, and controls another SH circuit corresponding to the another analog input terminal, from among the plurality of SH circuits, and the comparator, so as to sample the potential supplied to the another analog input terminal with the conversion operation and hold the potential as an analog value during the suspending.

2. The A/D converter according to claim 1, wherein:
the one SH circuit executes a first sampling operation for sampling the potential supplied to the one analog input terminal, and executes a first holding operation for holding a then analog value as a first analog value;
the comparator executes a first comparison operation for comparing the first analog value and the reference analog value, and outputs a result of the comparison as a first digital value; and
when the A/D conversion start request is generated for the potential supplied to the another analog input terminal during the comparator executing the first comparison operation, the arbitration circuit controls the comparator so as to suspend the first comparison operation, and controls the another SH circuit so as to execute a second sampling operation for sampling the potential supplied to the another analog input terminal and executes a second holding operation for holding an analog value as a second analog value.

3. The A/D converter according to claim 2, wherein,
when the first comparison operation is suspended and the second sampling operation and the second holding operation have been executed,
the arbitration circuit controls the comparator so as to restart the first comparison operation that is being suspended and output the first digital value, and controls the comparator so as to execute a second comparison operation for comparing the second analog value and the reference analog value and output a result of the comparison as a second digital value.

4. The A/D converter according to claim 3, wherein
when the A/D conversion start request is generated for the potential supplied to the another analog input terminal during the comparator executing the first comparison operation,
the arbitration circuit outputs a comparison operation suspension instruction to the comparator as a delay request, and the comparator suspends the first comparison operation that is being executed, in response to the comparison operation suspension instruction,
during a suspension period in which the comparator is suspending the first comparison operation, the arbitration circuit outputs a sampling operation execution instruction to the another SH circuit, and in response to the sampling operation execution instruction, the another SH circuit executes the second sampling operation and the second holding operation,
after the another SH circuit executing the second sampling operation, the arbitration circuit outputs a comparison operation restart instruction to the comparator for cancellation of the delay request, and in response to the comparison operation restart instruction, the comparator restarts the first comparison operation that is being suspended, and outputs the first digital value,
after the comparator outputting the first digital value, the arbitration circuit outputs a comparison operation execution instruction to the comparator, and in response to the comparison operation execution instruction, the comparator executes the second comparison operation, and outputs the second digital value.

5. The A/D converter according to claim 4, wherein:
when the A/D conversion start request is generated other than during the comparator executing the first comparison operation, but during the another SH circuit executing the first sampling operation,
the arbitration circuit outputs a sampling operation suspension instruction to the another SH circuit as the delay request, and the another SH circuit suspends the first sampling operation that is being executed, in response to the sampling operation suspension instruction,
during the suspension period in which another SH circuit is suspending the first sampling operation, the arbitration circuit outputs the sampling operation execution instruction to the another SH circuit, and in response to the sampling operation execution instruction, the another SH circuit executes the second sampling operation and the second holding operation,
after the another SH circuit executing the second sampling operation, the arbitration circuit outputs the comparison operation execution instruction to the comparator, the comparator, in response to the comparison operation execution instruction, executes the second comparison operation and outputs the second digital value,
after the comparator outputting the second digital value, the arbitration circuit outputs a sampling operation restart instruction to the another SH circuit for cancellation of the delay request, and in response to the sampling operation restart instruction, the another SH circuit restarts the first sampling operation that is being suspended, and executes the first holding operation, and
after the another SH circuit executing the first sampling operation, the arbitration circuit outputs the comparison operation execution instruction to the comparator, and in response to the comparison operation execution instruction, the comparator executes the first comparison operation, and outputs the first digital value.

6. The A/D converter according to claim 4, wherein the suspension period comprises time required for the plurality of SH circuits to execute sampling operations for sampling potentials supplied to the plurality of analog input terminals, respectively, and comprises an amount of time enabling the A/D converter to avoid an influence of power supply noise.

7. The A/D converter according to claim 6, wherein the amount of time enabling the A/D converter to avoid the influence of power supply noise is determined by measuring it in advance.

8. The A/D converter according to claim 3, further comprising:
a relay SH circuit, provided between the plurality of SH circuits and the comparator, the relay SH circuit including a first capacitor; and
a second capacitor in which a charge corresponding to the reference analog value is stored, wherein:
in the first capacitor, a charge corresponding to the first analog value is stored; and
the comparator executes the first comparison operation for comparing the first analog value, which corresponds to a potential supplied to the first capacitor, and the reference analog value, which corresponds to a potential supplied to the second capacitor, and outputs a result of the comparison as the first digital value.

9. The A/D converter according to claim 8, wherein
when the A/D conversion start request is generated simultaneously for potentials supplied to the another analog input terminal and still another analog input terminal from among the plurality of analog input terminals during the comparator executing the first comparison operation,
the another SH circuit executes the second sampling operation and the second holding operation,
the still another SH circuit executes a third sampling operation for sampling a potential supplied to an analog input terminal corresponding thereto and executes a third holding operation for holding a then third analog value,
if the still another SH circuit has higher priority over the another SH circuit,
the arbitration circuit
controls the relay SH circuit so as to store a charge corresponding to the third analog value in the first capacitor,
controls the comparator so as to execute a third comparison operation for comparing the third analog value, which corresponds to a potential supplied to the first capacitor, and the reference analog value, which corresponds to a potential supplied to the second capacitor, and outputs a result of the comparison as a third digital value,
controls the relay SH circuit so as to store a charge corresponding to the second analog value in the first capacitor, and
controls the comparator so as to execute the second comparison operation for comparing the second analog value, which corresponds to a potential supplied to the first capacitor, and the reference analog value, which corresponds to a potential supplied to the second capacitor, and outputs the result of the comparison as the second digital value.

10. An arbitration method applied to an A/D converter that includes a plurality of sample-and-hold circuits (hereinafter, “SH circuits”) provided corresponding to a plurality of analog input terminals, respectively, and a comparator, the arbitration method comprising:
Sampling, by a SH circuit from among the plurality of SH circuits, a potential supplied to one corresponding analog input terminal from among the plurality of analog input terminals and holding the potential as an analog value;
comparing, by the comparator, the analog value held by the one SH circuit and a reference analog value and outputting a result of the comparison as a digital value; and
when an A/D conversion start request is generated for a potential supplied to another analog input terminal from among the plurality of analog input terminals during a conversion operation for converting the potential supplied to the one analog input terminal into the digital value being executed,
suspending the conversion operation, and controlling another SH circuit corresponding to the another analog input terminal, from among the plurality of SH circuits, and the comparator so as to sample the potential supplied to the another analog input terminal with the conversion operation, and hold the potential as an analog value.

11. An A/D converter, comprising:
a plurality of sample-and-hold circuits (hereinafter, “SH circuits”) provided corresponding to a plurality of analog input terminals, respectively, in which one SH circuit from among the plurality of SH circuits samples a potential supplied to one corresponding analog input terminal from among the plurality of analog input terminals, and holds the potential as an analog value;
means for comparing the analog value held by the one SH circuit and a reference analog value, and outputting a result of the comparison as a digital value; and
means for, when an A/D conversion start request is generated for a potential supplied to another analog input terminal from among the plurality of analog input terminals during a conversion operation for converting the potential supplied to the one analog input terminal into the digital value being executed, suspending the conversion operation, and controlling another SH circuit corresponding to the another analog input terminal, from among the plurality of SH circuits, and the means for comparing, so as to sample the potential supplied to the another analog input terminal with the conversion operation and hold the potential as an analog value during the suspending.
